(19) United States
(12) Patent Application Publication
(10) Pub. No.: US 2007/0285685 A1
(43) Pub. Date: Dec. 13, 2007

(54) Image forming apparatus and image forming method

(75) Inventor: Masatsugu Hirayama, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignees: Kabushiki Kaisha Toshiba, Minato-ku (JP); Toshiba Tec Kabushiki Kaisha, Shinagawa-ku (JP)

(21) Appl. No.: 11/451,265

(22) Filed: Jun. 12, 2006

(51) Int. Cl. G03F 3/08

(52) U.S. Cl. 358/1.9; 358/518

(57) ABSTRACT

An image forming apparatus of the invention includes: an input unit configured to input color image data of multiple colors; a specified color converting unit configured to convert the input color image data of multiple colors to at least two specified colors with a color conversion table; a parameter setting unit configured to create the color conversion table and to set a parameter used for creation to be changeable; and an operation unit configured to change the parameter. According to the image forming apparatus of the invention, in an image forming apparatus capable of printing a color document in two colors, the criteria for converting multiple colors to two colors can be adjusted flexibly as the user desires or prefers.

### BACKGROUND OF THE INVENTION

1. Technical Field of the Invention

The present invention relates to an image forming apparatus and an image forming method, and more particularly, to an image forming apparatus and an image forming method that enable color printing.

2. Related Art

There has been an image forming apparatus, such as a color MFP (Multi-Function Peripheral), having the capability of reading a full-color document and printing the color document in two colors, for example, in red and black.

Such a color MFP makes a judgment as to a chromatic color and an achromatic color with respect to a color document, and prints a region determined as being a chromatic color, for example, in red and a region determined as being an achromatic color in black.

Conversion from color image data to color data of two colors is often based on color conversion processing using matrix computation or a look-up table. Regarding conversion to two colors, the occurrence of turbidity in color has been pointed out as a problem. For example, it is a problem that when a chromatic color is converted to red, the chromatic color is not necessarily converted to pure (high color saturation) red and may possibly be converted to cloudy red depending on kinds of color of the chromatic color.

In order to solve this color turbidity problem, for example, US-A1-2004-0239969 discloses a technique for performing two-color conversion not only in color conversion processing but also in inking processing.

The two-color printing capability provided to the image forming apparatus in the related art, however, uses fixed criteria for discriminating between an achromatic color and a chromatic color, and in some cases, the resulting two-color print is different from the result the user desires.

For example, in a case where the user prints a document, such as a magazine including a picture close to an achromatic color, although he expects that the picture will be printed in black, red may be mixed into part of the picture. In another case where dark red is included in the document, although the user wishes this dark red be printed in red, it may be printed in black in the resulting picture.

### SUMMARY OF THE INVENTION

The invention was devised in view of the foregoing circumstances, and therefore has an object to provide, in an image forming apparatus and an image forming method that enable a color document to be printed in two colors, an image forming apparatus and an image forming method with which the criteria for converting multiple colors to two colors can be adjusted flexibly as the user prefers.

In order to achieve the above and other objects, an image forming apparatus according to an aspect of the invention includes: an input unit configured to input color image data of multiple colors; a specified color converting unit configured to convert the input color image data of multiple colors to at least two specified colors with a color conversion table; a parameter setting unit configured to create the color conversion table and to set a parameter used for creation to be changeable; and an operation unit configured to change the parameter.

Also, in order to achieve the above and other objects, an image forming method according to another aspect of the invention includes the steps of: inputting color image data of multiple colors; converting the input color image data of multiple colors to at least two specified colors with a color conversion table; creating the color conversion table and setting a parameter used for creation to be changeable; and changing the parameter through an operation on an operation unit.

### BRIEF DESCRIPTION OF THE DRAWINGS

In the drawings:

FIG. 1 is a view showing an example of the overall configuration of an image forming apparatus according to one embodiment of the invention;

FIG. 2 is a flowchart showing one example of an image forming method (creation processing of a color conversion table for two colors) according to a first embodiment of the invention;

FIG. 3 is a view showing a first example of a display on an operation panel;

FIG. 4 is a flowchart showing one example of two-color conversion processing according to one embodiment of the invention;

FIG. 5 is a view showing one example of creation processing of a conversion table used for inking processing;

FIG. 6 is a view showing a second example of a display on the operation panel;

FIG. 7A through FIG. 7C are flowcharts showing one example of an image forming method (creation processing of a color conversion table for two colors) according to a second embodiment of the invention;

FIG. 8 is a view showing a third example of a display on the operation panel; and

FIG. 9 is a view showing a fourth example of a display on the operation panel.

### DETAILED DESCRIPTION OF PREFERRED EMBODIMENTS

Embodiments of an image forming apparatus and an image forming method of the invention will be described with reference to the accompanying drawings.

### (1) Configuration of Image Forming Apparatus

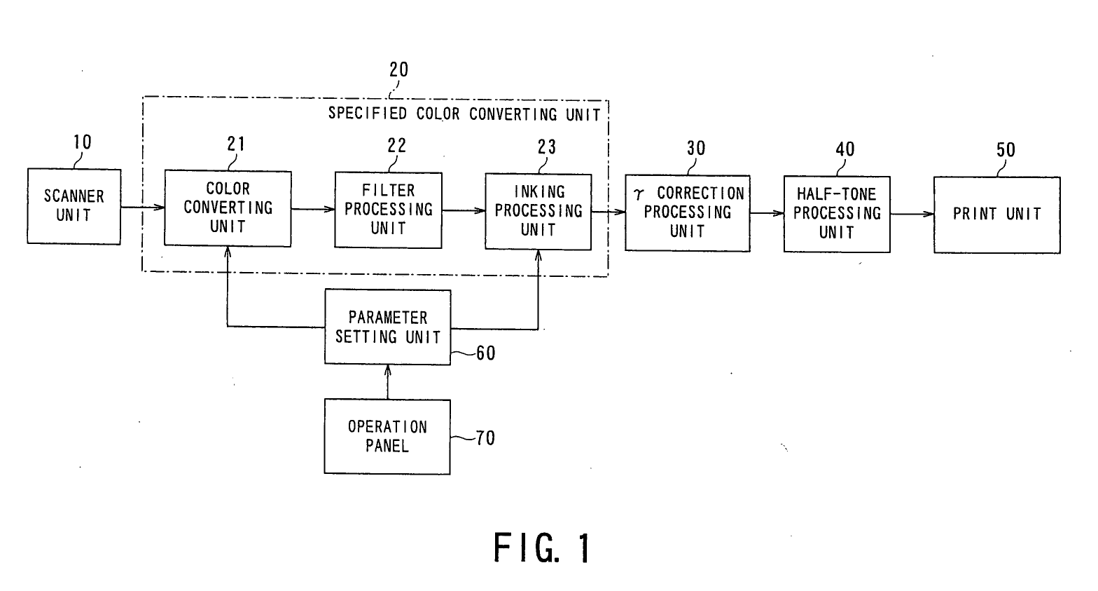

FIG. 1 is a view showing an example of the system configuration of an image forming apparatus 1 according to one embodiment.

The image forming apparatus 1 includes a scanner unit 10 (input unit) that reads a color document and inputs the document as first color image data expressed by three primary colors, R, G, and B (additive primary colors), a specified color converting unit 20 that converts the input first color image data to second color data of print colors, for example, Y (yellow), M (magenta), C (cyan), and black (K), by color conversion processing or inking processing, a parameter setting unit 60 that creates a color conversion table used for the color conversion processing in the specified color converting unit 20 and sets the parameter used for creation to be changeable, and an operation panel 70 (operation unit) through which the parameter is changed. The parameter setting unit 60 may be formed as part of a control unit (not shown) that controls the image forming apparatus 1 entirely.

The image forming apparatus 1 also includes a γ correction unit 30 that performs grayscale correction on the second color image data outputted from the specified color converting unit 20, a half-tone processing unit 40 that performs screen tone processing for printing or the like, and a print unit 50 that performs printing on a recording sheet or the like.

Of these components, the specified color converting unit 20 includes a color converting unit 21, a filter processing unit 22, and an inking processing unit 33 on the inside.

The color converting unit 21 converts three primary colors, R, G, and B, inputted from the scanner unit 10 to three print colors, Y, M, and C, or the like (subtractive primary colors), using the color conversion table (look-up table) or the like.

The filter processing unit 22 performs spatial filtering processing, such as enhancement processing and smoothing processing, on color-converted image data.

Also, the inking processing unit 33 performs processing to convert three print colors, Y, M, and C, or the like to four print colors further including black (k), that is, Y, M, C, and K, or the like. This conversion can be achieved also with the use of the conversion table or the like.

The color conversion table used in the color converting unit 21 is formed as a 3-D look-up table having a specific number of 3-D lattice points. At a 3-D lattice point (input lattice point) determined by the input values of R, G, and B, the values of C, M, and Y that should be outputted upon input of R, G, and B are stored (hereinafter, the values of C, M, and Y that should be outputted may occasionally be referred to as the values at an output lattice point for ease of explanation).

Normally, in a case where a color document of multiple colors that has been read is printed as a color document of multiple colors, a primary importance is placed on color reproducibility. In this case, values of C, M, and Y having color reproducibility are stored at an output lattice point for the values of R, G, and B at an input lattice point.

Meanwhile, in a case where a color document of multiple colors that has been read is converted, for example, to two specified colors and printed in these two colors, a two-color conversion look-up table, which is different from the look-up table used normally as described above, is used.

Hereinafter, creation processing of the look-up table for two-color conversion processing in this embodiment, and two-color conversion processing using this look-up table will be described in detail.

### (2) Creation Processing of Look-Up Table for Two-Color Conversion Processing (First Embodiment)

As has been described, when two colors are converted from input color data of multiple colors, the color conversion table (look-up table) for two colors is used. In the color conversion table for two colors, values of C, M, and Y corresponding to two colors, for example, black (achromatic color) and red (chromatic color), are stored at an output lattice point corresponding to an input lattice point.

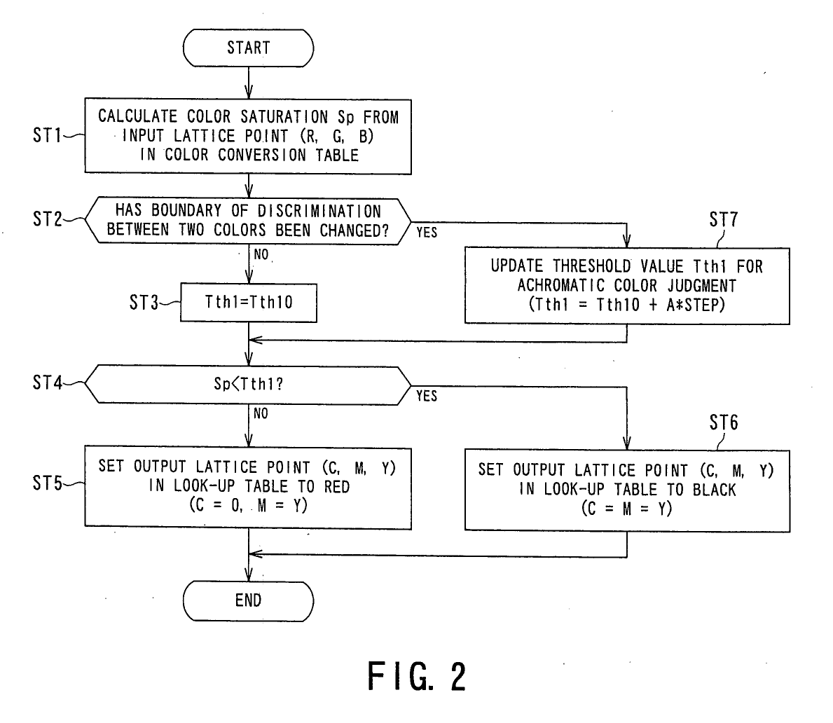

FIG. 2 is a flowchart showing one example of the flow of the creation processing of the color conversion table (look-up table) for two colors according to the first embodiment. In the first embodiment, for an input lattice point in the color conversion table for two colors (hereinafter, simply referred to as the color conversion table on occasion), a region of an achromatic color and a region of a chromatic color are discriminated from each other, and a color conversion table such that converts the region of an achromatic color to a first specified color, for example, black, and the region of a chromatic color to a second specified color, for example, red, is created.

In Step ST1, the color saturation Sp is calculated from the values of R, G, and B at an input lattice point in the color conversion table. The color saturation Sp is calculated using, for example, (Equation 1) as follows:

Sp=(R−G)²+(G−B)² (Equation 1)

Next, in Step ST2, whether the boundary of discrimination between two colors has been changed is determined. The change of the boundary of discrimination between two colors is set by the user through an operation on the operation panel 70. The parameter setting unit 60 monitors this setting state to determine whether the boundary of discrimination between two colors has been changed.

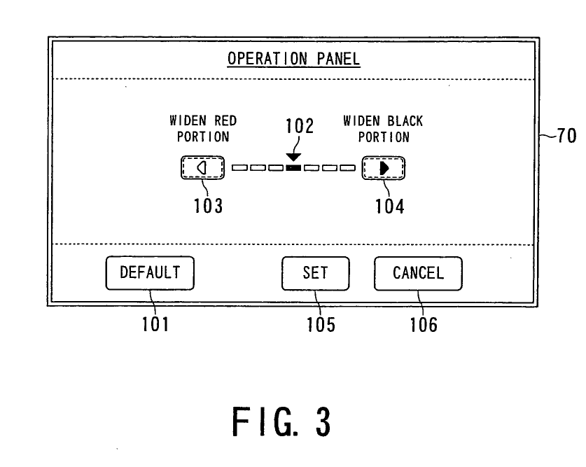

FIG. 3 is a view showing one example of a display on the operation panel 70. The operation panel 70 is formed, for example, by layering a liquid crystal display and a touch panel. On the liquid crystal display, texts, such as “widen red portion” and “widen black portion”, are displayed, and a “red widening button” 103 and a “black widening button” 104 are provided below these texts.

In addition, an indicator 102 is provided between the “red widening button” 103 and the “black widening button” 104 to indicate discrete STEP showing a change of the boundary, for example, in three steps in crosswise direction having the center position in between (three steps of “−1”, “−2”, and “−3” in the red direction and three steps of “+1”, “+2”, and “+3” in the black direction).

In the initial state (default state), the display is set in a state where the boundary of discrimination between two colors has not been changed (that is, STEP is set to “0”), and in this case, the indicator is displayed so that the center position is lit up.

Meanwhile, when the user depresses the “red widening button” 103 or the “black widening button” 104, the display of the indicator moves by one STEP either in the red direction or in the black direction each time the button is depressed. The change of the boundary of discrimination between two colors is confirmed when a “set” button 105 is depressed subsequently.

The parameter setting unit (control unit) 60 monitors the value of STEP, and determines that the boundary of discrimination between two colors has not been changed when STEP is set to “0”, and determines that the boundary of discrimination between two colors has been changed when STEP is set to a value other than “0”.

The confirmed value of STEP can be cancelled by depression of a “cancel” button 106, and the value can be set again. Also, the value of STEP that has been changed and set can be returned to “0” by depression of the “default” button.

When it is determined in Step ST2 that the boundary of discrimination between two colors has not been changed, the flow proceeds to Step ST3. In Step ST3, a threshold value Tth1 used for a judgment as to a chromatic color and an achromatic color is set to the default threshold value Tth10.

Next, in Step ST4, the color saturation Sp calculated in accordance with (Equation 1) and the threshold value Tth1 are compared with each other, and whether the input lattice point of interest is an achromatic color or a chromatic color is determined.

When the color saturation Sp is larger than the threshold value Tth1, the input lattice point is determined as being a chromatic color (NO in Step ST4). In this case, in Step ST5, the values of C, M, and Y at the output lattice point in the look-up table in the color converting unit 21 is set to reproduce red. For example, C=0 and M=Y are set. These set values have been previously stored, for example, in an appropriate ROM, and upon judgment as being a chromatic color, the values stored in the ROM are set as the values at the output lattice point in the look-up table.

Consequently, red is set at the output lattice point corresponding to the input lattice point determined as being a chromatic color.

On the contrary, when the color saturation Sp is smaller than the threshold value Tth1, the input lattice point of interest is determined as being an achromatic color (YES in Step ST4). In this case, in Step ST6, the values of C, M, and Y at the output lattice point in the look-up table in the color converting unit 21 are set to reproduce black. For example, C=M=Y is set.

Consequently, black is set at the output lattice point corresponding to the input lattice point determined as being an achromatic color.

The look-up table for two-color conversion is created by performing this processing on all the input lattice points.

This look-up table is the one for a case where the boundary of discrimination between two colors has not been changed. Hence, input lattice points are classified to a chromatic color and an achromatic color according to the threshold value set to the default value, and the look-up table having stored data of red at an output lattice point corresponding to an input lattice point of a chromatic color and data of black at an output lattice point corresponding to an input lattice point of an achromatic color is created. By using this look-up table for the color conversion processing, a color image of multiple colors is converted to a two-color image in red and black.

On the other hand, in a case where the user operates the “red widening button” 103 or the “black widening button” 104 on the operation panel 70 and sets STEP to a value other than “0” (other than the center position), it is determined that the boundary of discrimination between two colors has been changed (YES in Step ST2), and the flow proceeds to Step ST7.

In Step ST7, the threshold value Tth1 used for a judgment as to a chromatic color and an achromatic color is set to a value different from the default value Tth10. To be more concrete, it is set to a new threshold value Tth1 calculated in accordance with (Equation 2) below using the value of STEP set by the user through an operation on the operation panel 70:

Tth1=Tth10+A·STEP (Equation 2)

Herein, the value of STEP is a value other than “0”, for example, a value any of “+1” through “+3” or “−1” through “−3”. Also, A is an appropriate coefficient to weigh the value of STEP.

The threshold value Tth1 calculated in accordance with (Equation 2) is a value that can be changed by the value of STEP set by the user through the operation panel 70. This threshold value Tth1 is used for a judgment as to a chromatic color and an achromatic color (Step ST4), which enables the boundary between a region of a chromatic color and a region of an achromatic color to be changed. It is thus possible to change the boundary between two colors, red and black.

By repeating the processing shown in FIG. 2 as many times as the number of lattice points in the look-up table, the look-up table for two-color conversion can be created. The values at an output lattice point in this table can be changed by the “red widening button” 103 or the “black widening button” 104 on the operation panel 70.

According to the creation processing of the look-up table for the two-color conversion processing according to the first embodiment, it is possible to create a look-up table that enables the boundary of regions of two colors to be changed as the user desires or prefers with a simple operation.

### (3) Two-Color Conversion Processing

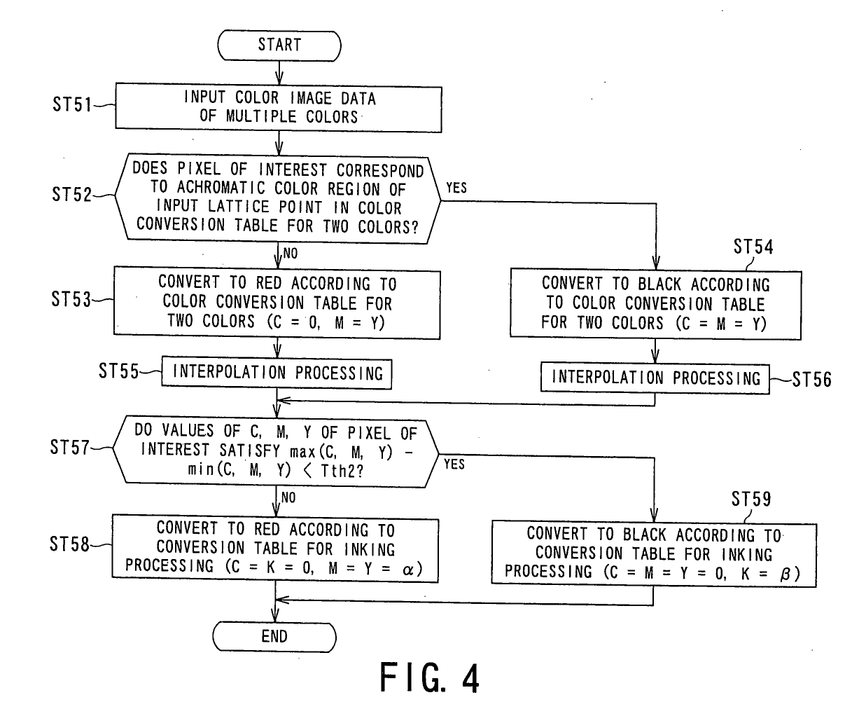

FIG. 4 is a flowchart showing one example of the flow of the two-color conversion processing using the color conversion table for two colors and the conversion table for the inking processing.

The values of R, G, and B inputted into the color converting unit 21 are multi-value data, for example, of 0 to 255. A color conversion table for two colors having a one-to-one correspondence to the multiple values is a 3-D table of 256×256×256 that needs a huge memory capacity.

Accordingly, in an embodiment often adopted, a memory capacity for the color conversion table for two colors is reduced by setting the number of lattice points in the color conversion table for two colors to be smaller than the number of multiple values to be inputted, while the values of corresponding C, M, and Y are calculated by interpolation processing when the values of R, G, and B as the values at intermediate points between lattice points are inputted.

In the case of this embodiment, even when the values of C, M, and Y at an output lattice point are set as C=0 and M=Y so that a chromatic color is converted to red, these values are not maintained intact after the interpolation processing. For example, there may be a case where the value of cyan (C) does not take complete 0. In this case, red after the interpolation processing is not pure red; instead, it is red slightly closer to cyan. Moreover, because the value after the interpolation processing varies slightly with the input values of R, G, and B, red that delicately differs in hue is outputted, which makes it impossible to achieve perfect two color conversion.

The same event occurs in a case where an achromatic color is converted to black, and black after the interpolation processing is not necessarily pure black.

Hence, the two-color conversion processing according to this embodiment solves this problem with the use of a conversion table for two-color conversion in the inking processing following the interpolation processing.

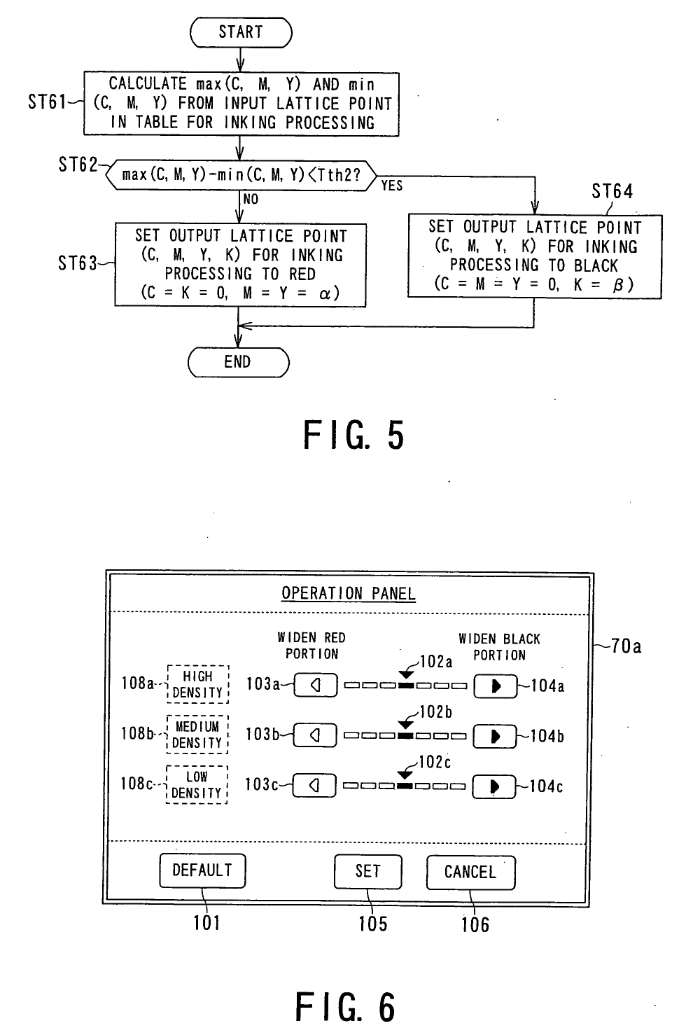

FIG. 5 is a view showing one example of a creation method of the conversion table for two-color conversion used in the inking processing.

Initially, in Step ST61, the maximum value, max(C, M, Y), and the minimum value, min(C, M, Y), are calculated from the values of C, M, and Y at an input lattice point in the conversion table for the inking processing.

Next, in Step ST62, a difference between the maximum value and the minimum value, (max(C, M, Y)−min(C, M, Y)), and a specific threshold value Tth2 are compared with each other.

In a case where a chromatic color is converted to red in two-color conversion by the color conversion processing, because C≅0, M≅Y>0 even after the interpolation processing, the minimum value is in close proximity to zero while the maximum value is far larger than zero. In short, a difference between the maximum value and the minimum value is a relatively large value. Hence, when it is determined in Step ST62 that the difference is larger than the threshold value Tth2, the flow proceeds to Step ST63.

In Step ST63, the values at the output lattice point in the conversion table for the inking processing are set to reproduce pure red. To be more concrete, C=K=0 and M=Y=α are set. It is thus possible to convert a chromatic color to pure red (M=Y) with neither cyan (C) nor black (K) being mixed after the inking processing.

Meanwhile, in a case where an achromatic color is converted to black in two-color conversion by the color conversion processing, C≅M≅Y even after the interpolation processing. Because the three values take almost the same value, a difference between the maximum value and the minimum value is a small value. Hence, when it is determined in Step ST62 that the difference is smaller than the threshold value Tth2, the flow proceeds to Step ST64.

In Step ST64, the values at the output lattice point in the conversion table for the inking processing are set to reproduce black. To be more concrete, for example, C=M=Y=0 and K=β are set. It is thus possible to convert an achromatic color to black (K) with none of C, M, and Y being mixed after the inking processing. It should be noted that α and β are values to set the density of red and black, respectively.

The conversion table for two-color conversion used in the inking processing is created by performing the processing as described above on all the input lattice points in the conversion table for the inking processing.

Referring to FIG. 4 again, the flow of the two-color conversion processing will be described.

Initially, in Step ST51, image data of multiple colors is inputted. The input image data is converted from multiple colors to two colors pixel by pixel.

In a case where the pixel of interest corresponds to a region of an achromatic color at an input lattice point in the color conversion table for two colors (YES in Step ST52), it is converted to black (C=M=Y) according to the color conversion table for two colors. This is because the two-color conversion table is created for an input lattice point of an achromatic color to be converted to black (C=M=Y).

Meanwhile, in a case where the pixel of interest corresponds to a region of a chromatic color at an input lattice point in the color conversion table for two colors (NO in Step ST52), it is converted to red (C=0, M=Y) according to the color conversion table for two colors.

Thereafter, the interpolation processing (Step ST55 and Step ST56) is performed for the values at an output lattice point in the color conversion table for two colors.

As the result of the interpolation processing, the values of C, M, and Y possibly take values slightly different from pure red and black. They are therefore converted again to pure red and black according to the conversion table for the inking processing.

In other words, in a case where the values of C, M, and Y of the pixel of interest satisfy (max(C, M, Y)−min(C, M, Y)<Tth2, they are converted again to pure black (C=M=Y=0, K=β) according to the conversion table for the inking processing.

On the contrary, in a case where the values of C, M, and Y of the pixel of interest do not satisfy (max(C, M, Y)−min(C, M, Y)<Tth2, they are converted again to pure red (C=K=0, M=Y=α) according to the conversion table for the inking processing.

As has been described, even in the embodiment where the interpolation processing is performed after the color conversion processing, it is possible to convert a chromatic color and an achromatic color to pure red and pure black without cyan or the like being mixed.

The color conversion table for two colors used in the two-color conversion processing described above is created according to the flowchart of FIG. 2. It is therefore possible to achieve two-color conversion processing as the user desires or prefers by using this color conversion table for two colors.

### (4) Creation Processing of Look-Up Table for Two-Color Conversion Processing (Second Embodiment)

There is a case where the user wishes to set the boundary between two colors more finely. For example, there is a case where the user wishes two-color conversion be performed in response to the density (or brightness) of a document in such a manner that a region of red is widened for a bright region and a region of black is widened for a dark region.

The second embodiment is an embodiment for creation processing of a look-up table for the two-color conversion processing that enables the setting of the boundary between two colors to be changed in response to density.

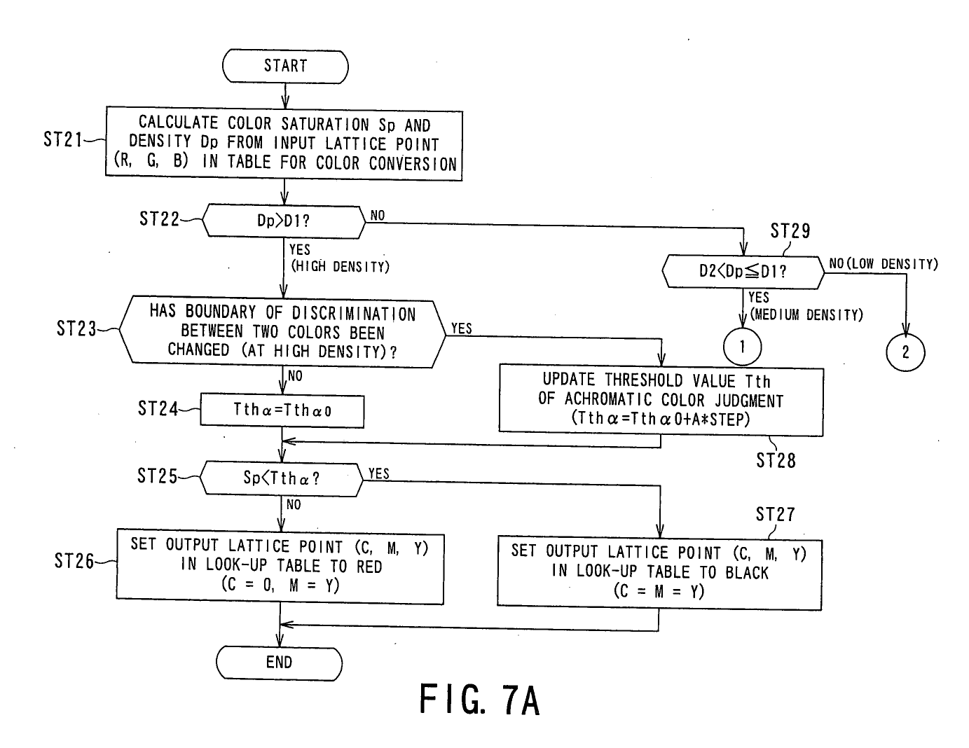

FIG. 6 is a view showing one example of a display on an operation panel 70a with which the density of a document can be classified into density segments of high density, medium density, and low density, so that the boundary between two colors is changed in response to the density segment. “Red widening buttons” 103a, 103b, and 103c and “black widening buttons” 104a, 104b, and 104c are provided, respectively, to indicators 108a, 108b, and 108c indicating the density segments. Between these buttons, indicators 102a, 102b, and 102c indicating STEP showing the movement of the boundary are provided correspondingly.

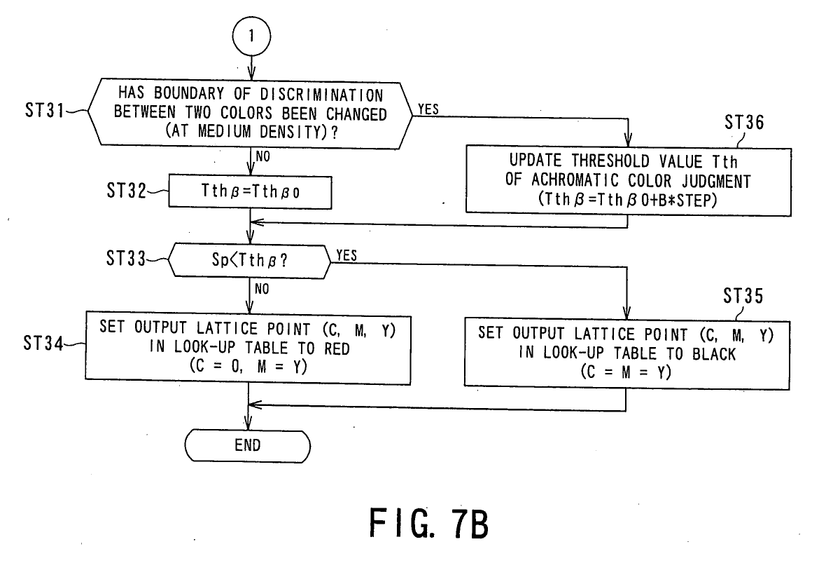

FIG. 7A through FIG. 7C are the flowcharts showing one example of the creation processing of the look-up table for the two-color conversion processing according to the second embodiment.

Initially, in Step ST21, the color saturation Sp and the density Dp are calculated from the values of R, G, and B at an input lattice point in the look-up table for color conversion. The color saturation Sp is calculated in accordance with (Equation 1) in the same manner as in the first embodiment. Meanwhile, the density Dp is calculated, for example, in accordance with (Equation 3) as follows:

Dp=255−(R+G+B)/3 (Equation 3)

Herein, the respective values of R, G, and B are values that fall within the range of 0 to 255.

Next, in Step ST 22 and Step ST29, the density Dp is classified into density segments of high density, medium density, and low density. The density classification is performed using appropriate threshold values D1 and D2 (D1>D2). More specifically, in a case where Dp>D1, the density is classified to high density (YES in Step ST22), and in a case where D2<Dp≦D1, the density is classified to medium density (YES in Step ST29); otherwise, the density is classified to low density (NO in Step ST29).

In a case where the density is classified to high density, the flow proceeds to Step ST23. Because the processing in Step ST23 through Step ST28 is basically the same as the processing in the first embodiment (FIG. 2), detailed description will be omitted. It should be noted, however, that the threshold value used for a judgment as to a chromatic color and an achromatic color is a threshold value Tthα for high density. Also, the value of STEP used in Step ST28 is a value set by the “red widening button” 103a or the “black widening button” 104a for high density on the operation panel 70a.

In a case where the density is classified to medium density, the flow proceeds to Step ST31. The processing in Step ST31 through Step ST36 is the same as the processing for high density. It should be noted, however, that the threshold value used for a judgment as to a chromatic color and an achromatic color is a threshold value Tthβ for medium density. Also, the value of STEP used in Step ST36 is a value set by the “red widening button” 103b or the “black widening button” 104b for medium density on the operation panel 70a.

Likewise, in a case where the density is classified to low density, processing in Step ST41 through Step ST46 is performed. It should be noted, however, that the threshold value used for a judgment as to a chromatic color and an achromatic color is a threshold value Tthγ for low density. Also, the value of STEP used in Step ST46 is a value set by the “red widening button” 103c or the “black widening button” 104c for low density on the operation panel 70a.

By performing the processing in FIG. 7A through FIG. 7C on all the lattice points in the look-up table, it is possible to create a look-up table corresponding to the setting of the boundary between two colors that has been set in response to the density segment.

According to the second embodiment, the user is able to make the setting for a change of the boundary between two colors finely in response to the density segment.

### (5) Other Embodiments

While the description has been given using red and black as the two converted colors by way of example, the two colors are not limited to red and black, and multiple colors can be converted to arbitrary two colors. In the two-color conversion processing, the final values of two colors are determined according to the conversion table for the inking processing, and the multiple colors can be converted to arbitrary two colors by a combination of the values of C, M, Y, and K set at an output lattice point in the conversion table for the inking processing. For example, by setting the values at an output lattice point so as to achieve Y=K=0 and C=M, a chromatic color can be converted to blue.

Also, by setting the values at an output lattice point to achieve M=K=0 and C=Y, an achromatic color can be converted to green.

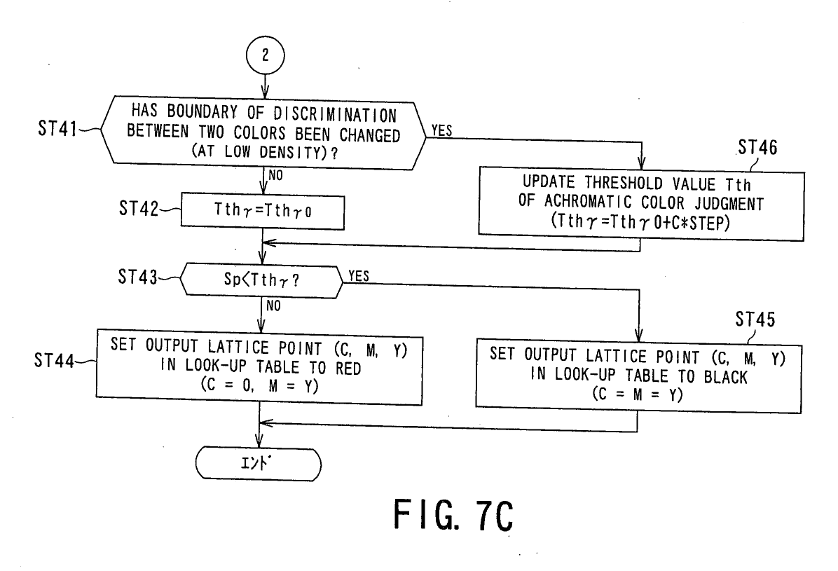

FIG. 8 shows an example of a display on an operation panel 70b according to an embodiment in which multiple colors are converted to two colors, blue and green. In this case, a text of “widen blue portion” is displayed instead of “widen red portion”, and a text of “widen green portion” is displayed instead of “widen black portion”. A “blue widening button” 108 and a “green widening button” 109 are provided below these texts. In addition, an indicator 110 same as the counterpart in the first embodiment is provided between these buttons.

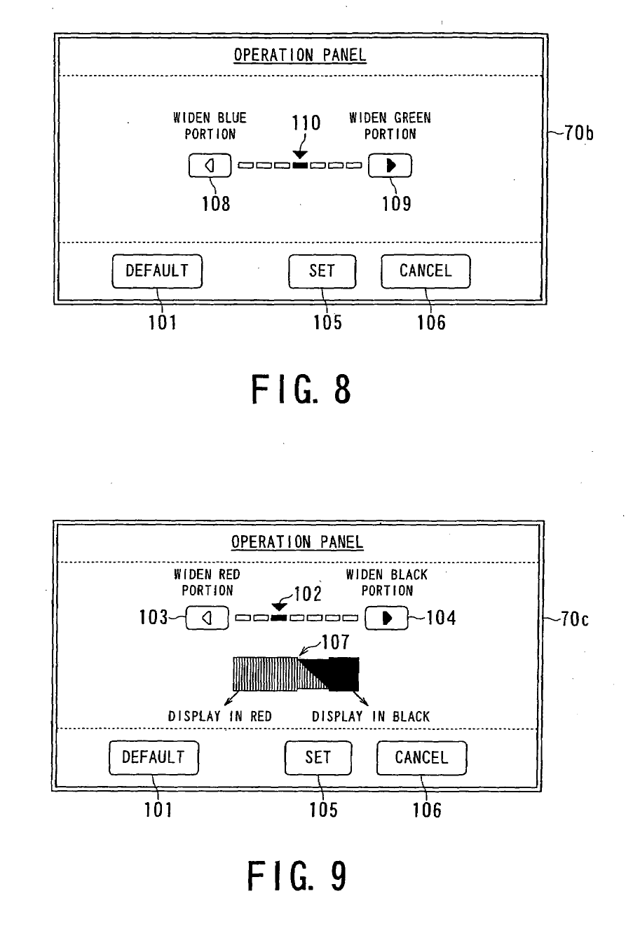

FIG. 9 is a view showing one embodiment of an operation panel 70c to which a color display unit 107 is provided additionally by way of example. The color display unit 107 is an indicator corresponding to two converted colors, and it is configured in such a manner that a ratio of relative lengths or areas is changed in response to the position of the indicator 102 changed by the settings made by the user. The color display unit 107 enables the user to make operations more intuitively.

As has been described, according to the image forming apparatus 1 of this embodiment, in an image forming apparatus capable of printing a color document in two colors, it is possible to adjust the criteria for converting multiple colors to two colors flexibly as the user desires or prefers.

It should be appreciated that the invention is not limited to the embodiments above, and it can be practiced by modifying components without deviating from the scope of the invention. Also, various inventions are possible by appropriately combining plural components disclosed in the embodiments above. For example, some components may be omitted from all the components shown in the embodiments. Further, components in different embodiments may be combined appropriately.

What is claimed is:

1. An image forming apparatus, comprising:
an input unit configured to input color image data of multiple colors;
a specified color converting unit configured to convert the input color image data of multiple colors to at least two specified colors with a color conversion table;
a parameter setting unit configured to create the color conversion table and to set a parameter used for creation to be changeable; and
an operation unit configured to change the parameter.

2. The image forming apparatus according to claim 1, wherein:
the parameter setting unit creates the color conversion table by discriminating between an achromatic color and a chromatic color as a color at an input lattice point in the color conversion table, setting a color at an output lattice point corresponding to an input lattice point identified as being the achromatic color to a first specified color, and setting a color at an output lattice point corresponding to an input lattice point identified as being the chromatic color to a second specified color.

3. The image forming apparatus according to claim 2, wherein:
the parameter set to be changeable by the parameter setting unit is a threshold value used to discriminate between the achromatic color and the chromatic color.

4. The image forming apparatus according to claim 2, wherein:
the first specified color is the achromatic color and the second specified color is an arbitrary chromatic color.

5. The image forming apparatus according to claim 2, wherein:
the operation unit is configured to enable a boundary of a region of the first specified color and a region of the second specified color to be changed; and
the parameter setting unit discriminates between the regions of the achromatic color and the chromatic color according to the boundary of the regions set through the operation unit.

6. The image forming apparatus according to claim 5, wherein:
the operation unit includes a color display unit configured to show a color display of colors corresponding to the first specified color and the second specified color in association with a change of the boundary of the regions.

7. The image forming apparatus according to claim 2, wherein:
the parameter setting unit classifies density of the color at an input lattice point in the color conversion table into plural density segments, and discriminates between the chromatic color and the achromatic color according to a threshold value set for each of the plural density segments through an operation on the operation unit.

8. The image forming apparatus according to claim 1, wherein the specified color converting unit includes:
a color converting unit configured to perform interpolation processing after additive primary colors are converted to subtractive primary colors using the color conversion table; and
an inking processing unit configured to convert the subtractive primary colors to mixtures of black and the subtractive primary colors, and
wherein, in a case where the color image data is converted to a first specified color and a second specified color, the color converting unit converts the color image data to image data of two colors including an achromatic color and a chromatic color, and the inking processing unit converts, of the image data of two colors, a region of the achromatic color to the first specified color and a region of the chromatic color to the second specified color.

9. The image forming apparatus according to claim 8, wherein:
the first specified color and the second specified color are arbitrary chromatic colors different from each other.

10. An image forming apparatus, comprising:
input means for inputting color image data of multiple colors;
specified color converting means for converting the input color image data of multiple colors to at least two specified colors with a color conversion table;
parameter setting means for creating the color conversion table and setting a parameter used for creation to be changeable; and
operation means for changing the parameter.

11. The image forming apparatus according to claim 10, wherein:
the parameter setting means creates the color conversion table by discriminating between an achromatic color and a chromatic color as a color at an input lattice point in the color conversion table, setting a color at an output lattice point corresponding to an input lattice point identified as being the achromatic color to a first specified color, and setting a color at an output lattice point corresponding to an input lattice point identified as being the chromatic color to a second specified color.

12. An image forming method, comprising the steps of:
inputting color image data of multiple colors;
converting the input color image data of multiple colors to at least two specified colors with a color conversion table;
creating the color conversion table and setting a parameter used for creation to be changeable; and
changing the parameter through an operation on an operation unit.

13. The image forming method according to claim 12, wherein:
in the step of setting the parameter, the color conversion table is created by discriminating between an achromatic color and a chromatic color as a color at an input lattice point in the color conversion table, setting a color at an output lattice point corresponding to an input lattice point identified as being the achromatic color to a first specified color, and setting a color at an output lattice point corresponding to an input lattice point identified as being the chromatic color to a second specified color.

14. The image forming method according to claim 13, wherein:
the parameter set in the step of setting the parameter is a threshold value used to discriminate between the achromatic color and the chromatic color.

15. The image forming method according to claim 13, wherein:
the first specified color is the achromatic color and the second specified color is an arbitrary chromatic color.

16. The image forming method according to claim 13, wherein:
in the step of changing the parameter, a boundary of a region of the first specified color and a region of the second specified color is changed; and
in the step of setting the parameter, the regions of the achromatic color and the chromatic color are discriminated from each other according to the boundary of the regions changed in the step of changing the parameter.

17. The image forming method according to claim 13, wherein:
the step of changing the parameter further includes the step of showing a color display of colors corresponding to the first specified color and the second specified color in association with a change of the boundary of the regions.

18. The image forming method according to claim 13, wherein:
in the step of setting the parameter, density of the color at an input lattice point in the color conversion table is classified into plural density segments, and the chromatic color and the achromatic color are discriminated from each other according to a threshold value set for each of the plural density segments through an operation on the operation unit.

19. The image forming method according to claim 12, wherein the step of converting the color image data to the two specified colors includes the steps of:
performing interpolation processing after additive primary colors are converted to subtractive primary colors using the color conversion table; and
performing inking processing by converting the subtractive primary colors to mixtures of black and the subtractive primary colors, and
wherein, in a case where the color image data is converted to a first specified color and a second specified color, in the step of performing the interpolation processing, the color image data is converted to image data of two colors including an achromatic color and a chromatic color, and in the step of performing the inking processing, of the image data of two colors, a region of the achromatic color is converted to the first specified color and a region of the chromatic color is converted to the second specified color.

20. The image forming method according to claim 19, wherein:
the first specified color and the second specified color are arbitrary chromatic colors different from each other.
